(19) United States
(12) Patent Application Publication
(10) Pub. No.: US 2009/0315084 A1
(43) Pub. Date: Dec. 24, 2009

(54) SEMICONDUCTOR DEVICE AND SEMICONDUCTOR SUBSTRATE

(76) Inventors: Dae-kil Cha, Seoul (KR); Won-Joo Kim, Hwaseong-si (KR); Tae-Hee Lee, Yongin-si (KR); Yoon-Dong Park, Yongin-si (KR)

Correspondence Address: F. CHAU & ASSOCIATES, LLC, 130 WOODBURY ROAD, WOODBURY, NY, 11797, US

(21) Appl. No.: 12/472,951

(22) Filed: May 27, 2009

(30) Foreign Application Priority Data
Jun. 23, 2008 (KR) 10-2008-0059057

(51) Int. Cl. H01L 29/73; H01L 29/06; H01L 29/78; H01L 21/306

(52) U.S. Cl. 257/288; 257/526; 438/689; 257/E29.02; 257/E29.174; 257/E29.255; 257/E21.215

(57) ABSTRACT

A semiconductor device includes a semiconductor substrate, a gate pattern disposed on the semiconductor substrate, a body region disposed on the gate pattern and a first impurity doping region and a second impurity doping region. The gate pattern is disposed below the body region and the first impurity doping region and the second impurity doping region.

### CROSS-REFERENCE TO RELATED APPLICATIONS

This application claims the benefit of Korean Patent Application No. 10-2008-0059057, filed on Jun. 23, 2008, the disclosure of which is hereby incorporated by reference herein in its entirety.

### BACKGROUND

1. Technical Field

Exemplary embodiments of the present invention relate to a semiconductor device and to a semiconductor substrate, and more particularly, to a semiconductor device and to a semiconductor substrate which each include gate patterns disposed below a body region.

2. Description of the Related Art

Recently, conventional 1-transistor dynamic random access memories (1-T DRAMs) which are configured by a single transistor without a capacitor have been used. 1-T DRAMs can be manufactured using a simple manufacturing process, and have an improved sensing margin.

However, there may be some difficulties associated with conventional 1-T DRAMs such as, for example, the distance between the gate pattern WL and each of the impurity doping regions may be short, thereby possibly creating a band to band tunneling (BTBT) phenomenon. In addition, with conventional 1-T DRAMs, data destruction can occur due to repeated reading of data and increased retention time.

Thus, there is a need in the art to overcome the above-mentioned drawbacks associated with conventional 1-T DRAMs.

### SUMMARY OF THE INVENTION

Exemplary embodiments of the present invention include a semiconductor device and a semiconductor substrate which each include gate patterns disposed below a body region.

In accordance with an exemplary embodiment of the present invention a semiconductor device is provided. The semiconductor device includes a semiconductor substrate, a gate pattern disposed on the semiconductor substrate, a body region disposed on the gate pattern; and a first impurity doping region and a second impurity doping region. The gate pattern is disposed below the body region and the first impurity doping region and the second impurity doping region.

The first impurity doping region and the second impurity doping region may protrude in an upwards direction from the body region, and are spaced a predetermined interval apart, and the semiconductor device may further comprise a block insulating region disposed between the first impurity doping region and the second impurity doping region.

The semiconductor device may further comprise a buried oxide (BOX) insulating region disposed between the semiconductor substrate and the gate pattern.

The semiconductor device may further comprise a gate insulating region disposed between the gate pattern and the body region.

The semiconductor device may further comprise a first insulating region disposed at both sides of each of the gate pattern and the body region, wherein the first insulating region insulates the gate pattern and the body region from their surroundings.

The first impurity doping region may be connected to one of a source line or a bit line; and the second impurity doping region may be connected to one of a bit line or a source line. The semiconductor device may comprise a bipolar junction transistor (BJT), the word line pattern may be coupled to a base region of the BJT, and the first and second impurity doping regions may be an emitter region and a collector region, respectively, or, the first and second impurity doping regions are a collector region and an emitter region, respectively.

The body region may be a floating body region separated from the semiconductor substrate; and the body region and the semiconductor substrate may be formed of materials having the same properties.

In accordance with an exemplary embodiment of the present invention, a semiconductor substrate is provided. The semiconductor substrate includes a substrate region, a buried oxide (BOX) insulating region disposed above the substrate region, a gate pattern separated from the substrate by a first insulating region, and disposed above the BOX insulating region and a gate insulating region disposed above the gate pattern. The semiconductor substrate further includes a floating body region separated from the gate pattern by the gate insulating region, and disposed on the gate insulating region. The substrate region and the floating body region are formed of materials having the same properties.

In accordance with an exemplary embodiment of the present invention a method of manufacturing a semiconductor substrate is provided. The method includes forming at least one floating body pattern by etching a bulk substrate, dividing the bulk substrate into a substrate region and a floating body region by etching a bulk region below the at least one floating body pattern and forming a gate pattern between the floating body region and the substrate region.

Prior to the forming of the gate pattern, the method may further comprise forming a BOX insulating region on the substrate region, and after the forming of the gate pattern, the method may further comprise forming a gate insulating region on the gate pattern.

### BRIEF DESCRIPTION OF THE DRAWINGS

Exemplary embodiments of the present invention can be understood in more detail from the following description taken in conjunction with the accompanying drawings of which:

FIG. 1 FIG. 1 illustrates a cross-sectional view of a 1-transistor dynamic random access memory (1-T DRAM) as an example for comparison with an exemplary embodiment the present invention;

FIG. 2 is a circuit diagram of the 1-T DRAM of FIG. 1 on which modeling is performed;

FIG. 3 is a cross-sectional view of a semiconductor device according to an exemplary embodiment of the present invention;

FIG. 4 is a circuit diagram of the semiconductor device of FIG. 3 on which modeling is performed;

FIG. 5 is a graph of a bit line current with respect to the number of read operations performed in structures of FIGS. 1 and 3;

FIG. 6 is a graph of a drain current with respect to a retention time in structures of FIGS. 1 and 3;

FIG. 7 is a front view of semiconductor devices arranged in the form of an array, according to an exemplary embodiment of the present invention;

FIGS. 8A and 8B are circuit diagrams of the semiconductor devices of FIG. 7 on which modeling is performed, according to an exemplary embodiment of the present invention;

FIGS. 9A and 9B are circuit diagrams of the semiconductor devices of FIG. 7 on which modeling is performed, according to an exemplary embodiment of the present invention;

FIGS. 10 through 13 are views for explaining read and write operations of semiconductor devices, according to an exemplary embodiment of the present invention;

FIG. 14 is a perspective view of a semiconductor substrate according to an exemplary embodiment of the present invention;

FIG. 15 is a perspective view of a substrate region and a body region of the semiconductor substrate of FIG. 14;

FIG. 16 illustrates the case where a buried oxide (BOX) region, a gate pattern, and a gate insulating region are formed between a substrate region and a body region in FIG. 14;

FIGS. 17A through 17H are perspective views of a method of manufacturing a semiconductor device, according to an exemplary embodiment of the present invention; and

FIGS. 18A through 18G are perspective views of a method of manufacturing a semiconductor device, according to an exemplary embodiment of the present invention.

### DETAILED DESCRIPTION OF THE EXEMPLARY EMBODIMENTS OF THE PRESENT INVENTION

Reference will now be made in detail to embodiments, examples of which are illustrated in the accompanying drawings, wherein like reference numerals refer to the like elements throughout. In this regard, the present invention may be embodied in many different forms and should not be construed as being limited to the exemplary embodiments set forth herein. Accordingly, exemplary embodiments are merely described below, by referring to the figures, to explain aspects of the present invention.

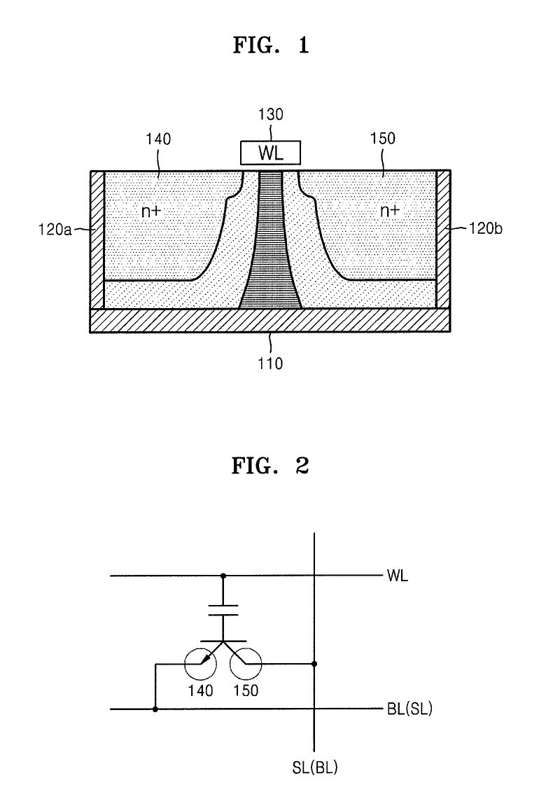

FIG. 1 illustrates a cross-sectional view of a 1-transistor dynamic random access memory (1-T DRAM) as an example for comparison with an exemplary embodiment of the present invention.

FIG. 2 is a circuit diagram of the 1-T DRAM of FIG. 1 on which modeling is performed.

Referring to FIGS. 1 and 2, the 1-T DRAM of the comparative example can be modeled in the form of a bipolar junction transistor (BJT), but substantially has a structure of a metal oxide semiconductor (MOS) transistor. Thus, with the 1-T DRAM of the comparative example, a gate pattern 130 is disposed above a body region including impurity doping regions 140 and 150. Accordingly, the distance between the gate pattern WL and each of the impurity doping regions 140 and 150 is short, thereby possibly creating a band to band tunneling (BTBT) phenomenon. In addition, with the 1-T DRAM of the comparative example, data destruction can occur due to repeated reading of data and increased retention time.

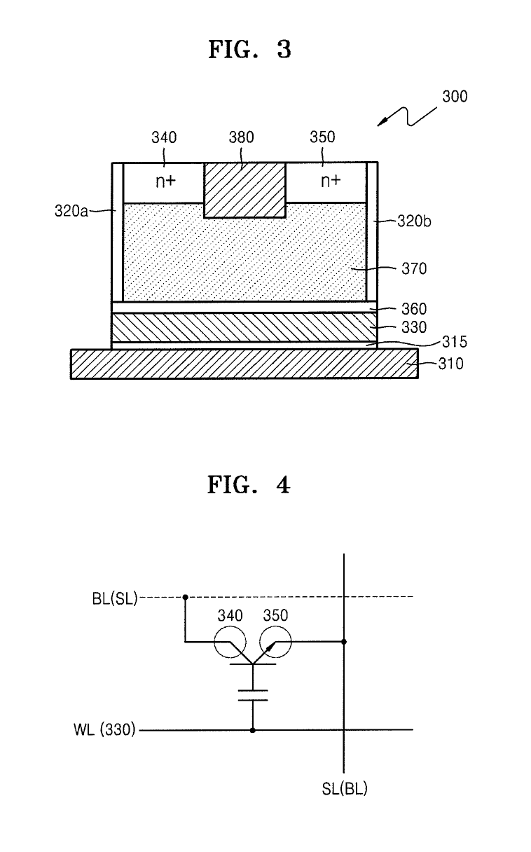

FIG. 3 is a cross-sectional view of a semiconductor device 300 according to an exemplary embodiment of the present invention.

Referring to FIG. 3, the semiconductor device 300 includes a semiconductor substrate 310, a gate pattern 330, a body region 370, a first impurity doping region 340 and a second impurity doping region 350.

The gate pattern 330 is disposed above the semiconductor substrate 310. The body region 370 is disposed above the gate pattern 330. The first and second impurity doping regions 340 and 350 are disposed above the body region 370. That is, the gate pattern 330 is disposed below the body region 370 and the first and second impurity doping regions 340 and 350.

With the semiconductor device 300, as the gate pattern 330 is disposed below the first and second impurity doping regions 340 and 350, the distance between gate patterns 330 and the first and second impurity doping regions 340 and 350 is large. Thus, with the semiconductor device 300, the BTBT phenomenon can be prevented. For example, the distance between the gate patterns 330a and 330b and the first and second impurity doping regions 340 and 350 is greater than in the case of the comparative example of FIG. 1.

The first impurity doping region 340 and the second impurity doping region 350 may protrude in an upwards direction from the body region 370, and may be spaced a predetermined interval apart. A block insulating region 380 is disposed between the first impurity doping region 340 and the second impurity doping region 350.

The block insulating region 380 may be formed of, for example, a material including oxide. However, the block insulating region 380 may be replaced by an insulating region formed of another insulating material. Throughout this specification, oxide regions may be replaced by, for example, insulating regions formed of an insulating material except oxide.

The semiconductor device 300 may further include, for example, a buried oxide (BOX) region 315 formed on the semiconductor substrate 310. The BOX region 315 may be formed by, for example, forming an oxide region on the semiconductor substrate 310 formed from a bulk substrate. Alternatively, for example, an insulating region of a silicon-on-insulator (SOI) substrate may be used as the BOX region 315.

The semiconductor device 300 may further include first insulating regions 320a and 320b. The first insulating regions 320a and 320b are disposed at both sides of each of the gate pattern 330 and the body region 370, respectively. The first insulating regions 320a and 320b insulate the gate pattern 330 and the body region 370 from their surroundings.

The semiconductor device 300 may further include a gate insulating region 360. The gate insulating region 360 is disposed on the gate pattern 330. The gate insulating region 360 may be disposed between the gate pattern 330 and the body region 370.

The body region 370 may be a floating body region separated from the semiconductor substrate 310. The body region 370 and the semiconductor substrate 310 may be formed of materials having the same properties, which will be described later.

FIG. 4 is a circuit diagram of the semiconductor device 300 of FIG. 3 on which modeling is performed.

Referring to FIG. 4, the first impurity doping region 340 of the semiconductor device 300 of FIG. 3 may be connected to a source line SL, and the second impurity doping region 350 may be connected to a bit line BL. Alternatively, the first impurity doping region 340 may be connected to the bit line BL, and the second impurity doping region 350 may be connected to the source line SL.

The semiconductor device 300 of FIG. 3 may function as a BJT transistor. The gate patterns 330 may be a base region of the BJT transistor. The first and second impurity doping regions 340 and 350 may be an emitter region and a collector region of the BJT transistor, respectively. Alternatively, the first and second impurity doping regions 340 and 350 may be the collector region and the emitter region of the BJT transistor, respectively.

The base region of the BJT transistor may be a floating region.

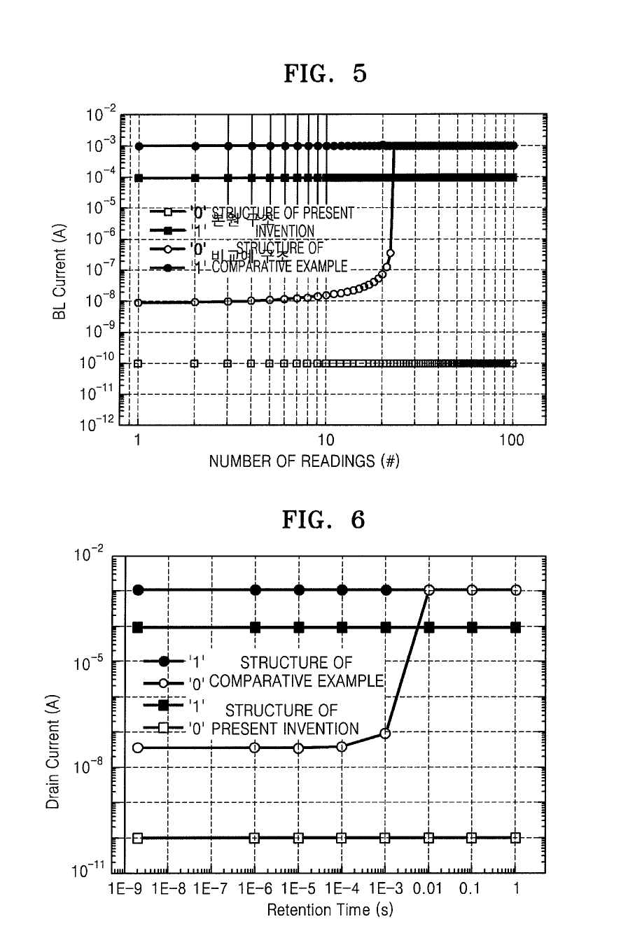

FIG. 5 is a graph of a bit line BL current with respect to the number of read operations performed in the structures of FIGS. 1 and 3.

Referring to FIG. 5, in the 1-T DRAM of the comparative example of FIG. 1, when a read operation is repeated about 10 times or more, a data state ‘0’ is shown not to be distinguishable from a data state ‘1’. On the other hand, in the semiconductor device 300 of FIG. 3, although a read operation is repeated up to about 100 times, the data state ‘0’ can be distinguished from the data state ‘1’.

FIG. 6 is a graph of a drain current with respect to a retention time in the structures of FIGS. 1 and 3.

Referring to FIG. 6, in the 1-T DRAM of the comparative example of FIG. 1, when a retention time exceeds about 10 ms, a data state ‘0’ is shown not to be distinguishable from a data state ‘1’. On the other hand, in the semiconductor device 300 of FIG. 3, although a retention time is about 1 s, the data state ‘0’ can be clearly distinguished from the data state ‘1’.

Semiconductor devices may be arranged in the form of an array.

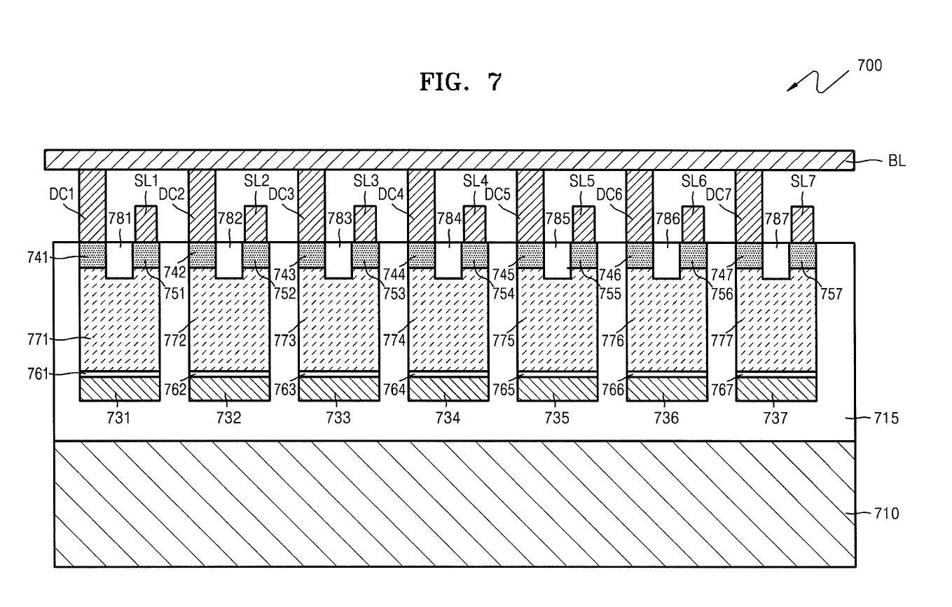

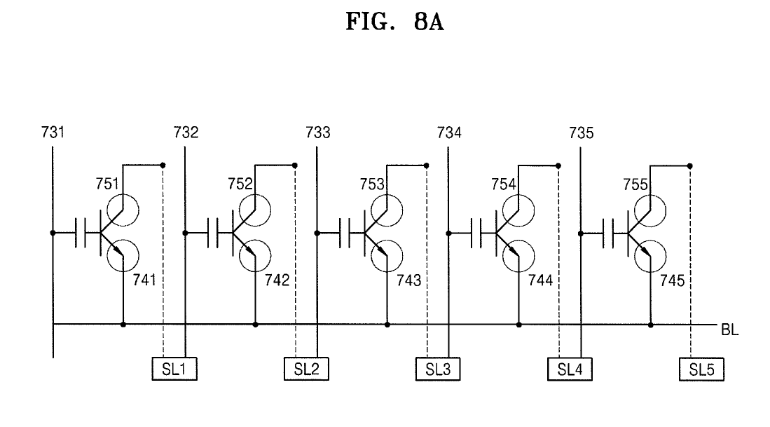

FIG. 7 is a front view of the semiconductor devices of 700 arranged in the form of an array, according to an exemplary embodiment of the present invention.

Referring to FIG. 7, a plurality of body regions 771 through 777 and a plurality of gate patterns 731 through 737 are disposed on a semiconductor substrate 710 in the form of an array. The gate patterns 731 through 737 may be disposed between the semiconductor substrate 710 and the body regions 771 through 777, respectively.

First impurity doping regions 741 through 747 and second impurity doping regions 751 through 757 may be disposed above the body regions 771 through 777, respectively. Block insulating regions 781 through 787 may be disposed between the first impurity doping regions 741 through 747 and the second impurity doping regions 751 through 757, respectively. A BOX region 715 may further be disposed on the semiconductor substrate 710, second insulating regions 762 through 767 may be disposed between the gate patterns 731 through 737 and the body regions 771 through 777, respectively.

The first impurity doping regions 741 through 747 may be connected to a bit line BL, and the second impurity doping regions 751 through 757 may be connected to source lines SL1 through SL7, respectively. Alternatively, the first impurity doping regions 741 through 747 may be respectively connected to the source lines SL1 through SL7, and the second impurity doping regions 751 through 757 may be connected to the bit line BL.

As the semiconductor devices 700 arranged in the form of an array are viewed from the front in FIG. 7, only semiconductor devices disposed at the frontmost side are illustrated. However, other semiconductor devices may be disposed behind these semiconductor devices 700.

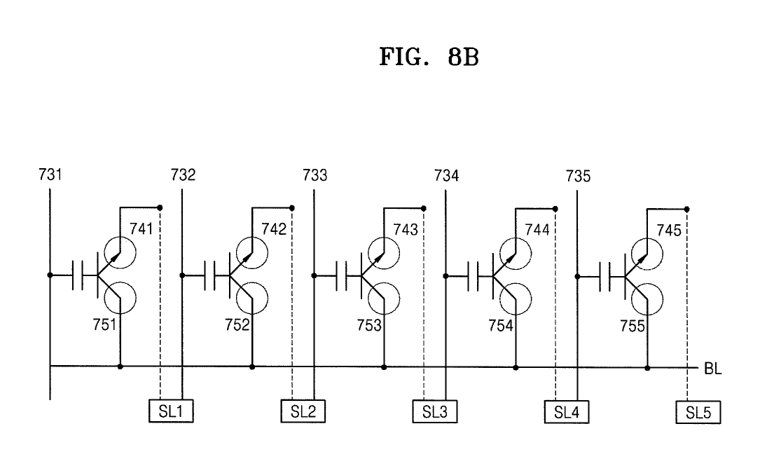

FIG. 8A is a circuit diagram of the semiconductor devices 700 of FIG. 7 on which modeling is performed, according to an exemplary embodiment of the present invention.

Referring to FIG. 8A, the semiconductor devices 700 are connected to gate patterns 731 through 735, respectively. The gate patterns 731 through 735 may function as a word line. First impurity doping regions 741 through 745 of the semiconductor devices 700 may be connected to a single bit line BL. Second impurity doping regions 751 through 755 of the semiconductor devices 700 may be connected to the source lines SL1 through SL5, respectively.

FIG. 8B is a circuit diagram of the semiconductor devices 700 of FIG. 7 on which modeling is performed, according to an exemplary embodiment of the present invention.

In the semiconductor devices 700 of FIG. 8B, the first impurity doping regions 741 through 745 are connected to the source lines SL1 through SL5, respectively. The second impurity doping regions 751 through 755 are connected to the signal bit line BL. Except for this, the semiconductor devices of FIG. 8B are the same as the semiconductor devices of FIG. 8A.

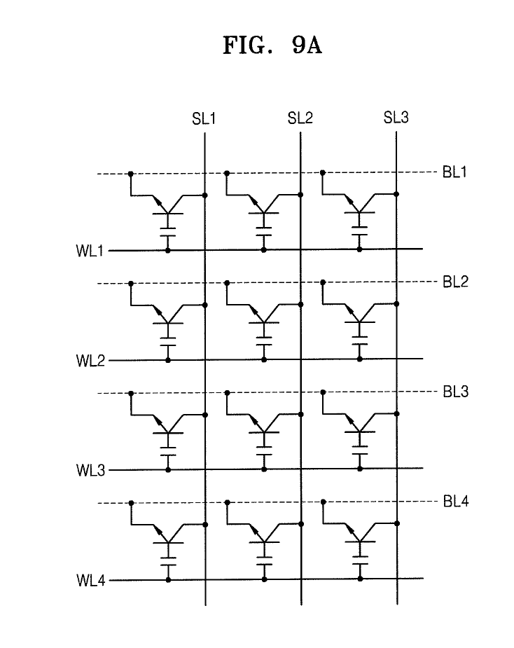

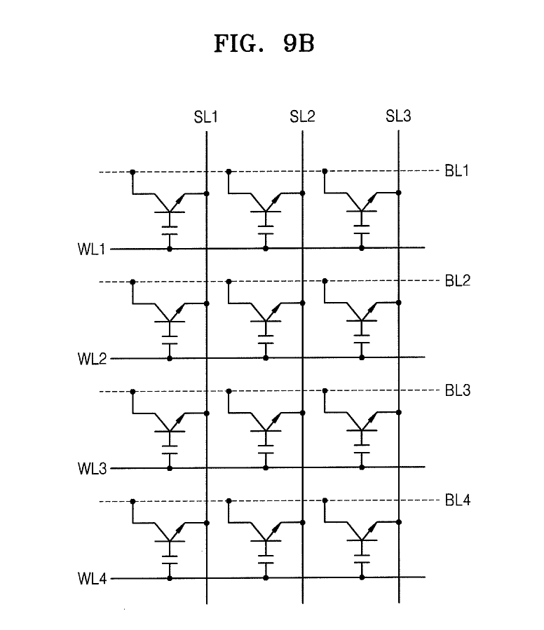

FIGS. 9A and 9B are circuit diagrams of the semiconductor devices 700 of FIG. 7 on which modeling is performed, according to exemplary embodiments of the present invention.

Referring to FIGS. 9A and 9B, the semiconductor devices 700 are connected to a plurality of bit lines BL1 through BL4, a plurality of source lines SL1 through SL3 and a plurality of word lines WL1 through WL4.

As the circuit diagrams of FIGS. 9A and 9B are views of a plurality of circuits that are the same as the circuits of FIGS. 8A and 8B, respectively, their detailed descriptions will not be repeated here.

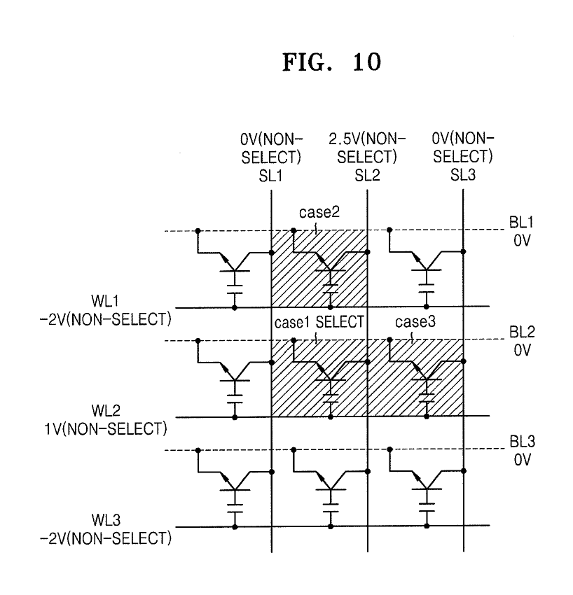

FIGS. 10 and 11 are views for explaining processes of writing data ‘1’ in a semiconductor device and testing whether the data ‘1’ is written or not, according to an exemplary embodiment of the present invention.

Referring to FIG. 10, a semiconductor device indicated by CASE1 is a writing target semiconductor device. For example, about 1 V is applied to word line WL2 connected to the writing target semiconductor device, and about −2 V is applied to other word lines WL1 and WL3. For example, about +2.5 V is applied to a source line SL2 connected to the writing target semiconductor device, and about 0 V is applied to other source lines SL1 and SL3. In addition, for example, about 0 V is applied to bit lines BL1 through BL3.

A semiconductor device indicated by CASE2 is one of a plurality of semiconductor devices connected to the source line SL2 of the writing target semiconductor device. A semiconductor device indicated by CASE 3 is one of a plurality of semiconductor devices connected to the bit line BL2 of the writing target semiconductor device.

Referring to FIG. 11, in a first graph, the case (e.g., PGM) where data ‘1’ is written in the writing target semiconductor device and the case (e.g., READ) where the data ‘1’ is read are illustrated. In a second graph, the case where data ‘1’ is not written in the semiconductor device connected to the source line SL2 of the writing target semiconductor device is illustrated. In a third graph, the case where data ‘1’ is not written in the semiconductor device connected to the bit line BL2 of the writing target semiconductor device is illustrated.

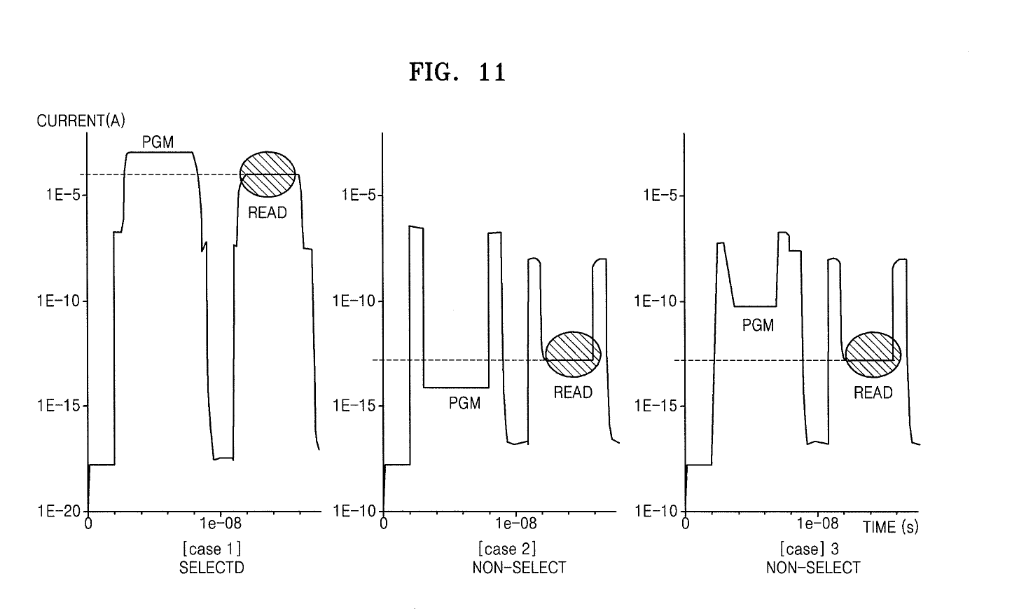

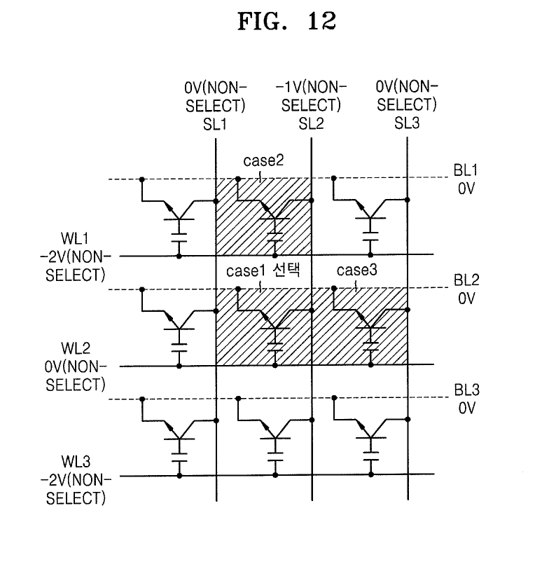

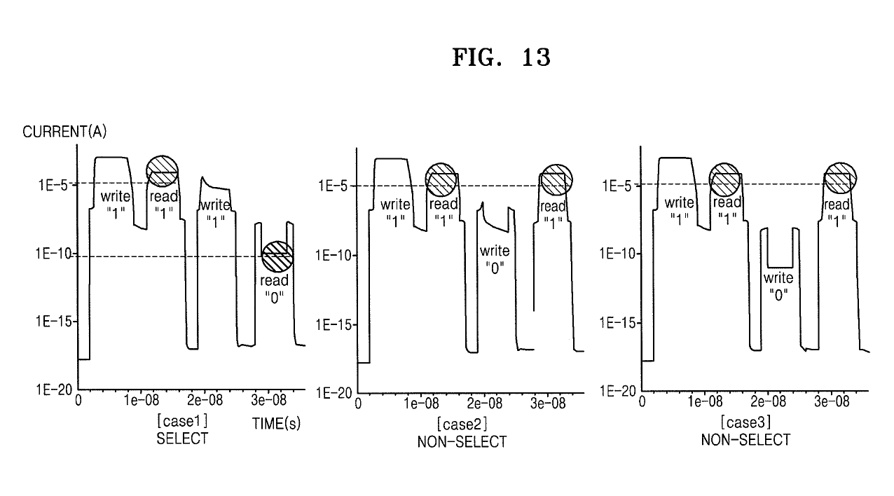

FIGS. 12 and 13 are views for explaining processes of writing data ‘0’ in a semiconductor device and testing whether the data ‘0’ is written or not, according to another exemplary embodiment of the present invention.

Referring to FIG. 12, a semiconductor device indicated by CASE1 is a writing target semiconductor device. For example, about 0 V is applied to the word line WL2 connected to the writing target semiconductor device, and about −2 V is applied to other word lines WL1 and WL3. For example, about −1 V is applied to the source line SL2 connected to the writing target semiconductor device, and about 0 V is applied to other source lines SL1 and SL3. In addition, for example, about 0 V is applied to the bit lines BL1 through BL3.

A semiconductor device indicated by CASE2 is one of a plurality of semiconductor devices connected to the source line SL2 of the writing target semiconductor device. A semiconductor device indicated by CASE3 is one of a plurality of semiconductor devices connected to the bit line BL2 of the writing target semiconductor device.

Referring to FIG. 13, in a first graph, the case (e.g., PGM) where data ‘0’ is written in the writing target semiconductor device and the case (e.g., READ) where the data ‘0’ is read are illustrated. In a second graph, the case where data ‘0’ is not written in the semiconductor device connected to the source line SL2 of the writing target semiconductor device is illustrated. In a third graph, the case where data ‘0’ is not written is illustrated.

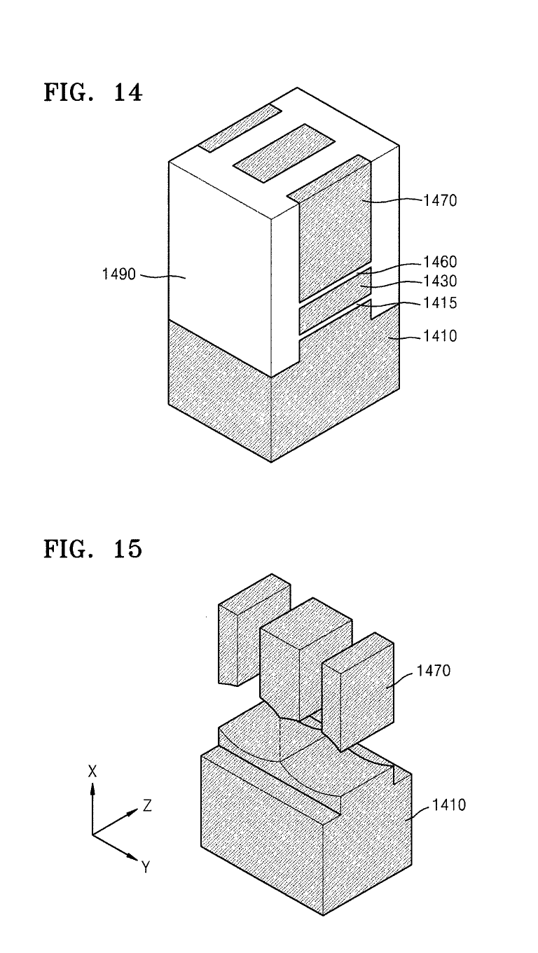

FIG. 14 is a perspective view of a semiconductor substrate according to an exemplary embodiment of the present invention.

Referring to FIG. 14, the semiconductor substrate according to the present exemplary embodiment includes a substrate region 1410, a gate pattern 1430 and a body region 1470.

The body region 1470 may be separated from the substrate region 1410. That is, the body region 1470 is a floating body region. The substrate region 1410 and the body region 1470 may be formed of materials having the same property.

The gate pattern 1430 is disposed between the substrate region 1410 and a body region 1470, and is separated from the substrate region 1410 and the body region 1470. To achieve this, a BOX region 1415 may be disposed between the substrate region 1410 and the gate pattern 1430, and a gate insulating region 1460 may be disposed between the gate pattern 1430 and the body region 1470. The BOX region 1415 insulates the substrate region 1410 from the gate pattern 1430. The gate insulating region 1460 insulates the gate pattern 1430 from the body region 1470.

A first insulating region 1490 is disposed at both sides of each of the gate pattern 1430 and the body region 1470. The first insulating region 1490 insulates the gate pattern 1430 and the body region 1470 from surroundings.

For example, the BOX region 1415, the gate insulating region 1460 or the first insulating region 1490 may be formed of silicon oxide, or alternatively, may be formed of different insulating materials. In addition, the BOX region 1415, the gate insulating region 1460 or the first insulating region 1490 may be formed of at least two insulating materials.

To manufacture the semiconductor substrate according to the present exemplary embodiment, a bulk substrate can be divided into upper and lower portions by selectively etching the middle portion of the bulk substrate. The upper and lower portions, which are separated from each other, may be the body region 1470 and the substrate region 1410, respectively. In addition, at least one body region may be formed by, for example, forming at least one body pattern and then etching a bulk region below the body pattern.

After forming the substrate region 1410 and the body region 1470, which are separated from each other, the gate pattern 1430 is formed between the substrate region 1410 and the body region 1470. If the BOX region 1415 and the gate insulating region 1460 are formed, the BOX region 1415 may be formed between the substrate region 1410 and the body region 1470, and then the gate pattern 1430 may be formed on the BOX region 1415. Then, the gate insulating region 1460 may be formed on the gate pattern 1430.

A first impurity doping region and a second impurity doping region may be further formed on the semiconductor substrate according to the present exemplary embodiment. Like in the case of FIG. 3, the first and second impurity doping regions may be formed above the body region 1470. Thus, the gate pattern 1430 is disposed below the body region 1470 and the first and second impurity doping regions.

FIG. 15 is a perspective view of the substrate region 1410 and the body region 1470 of the semiconductor substrate of FIG. 14. Referring to FIG. 15, the substrate region 1410 and the body region 1470 are separated from each other.

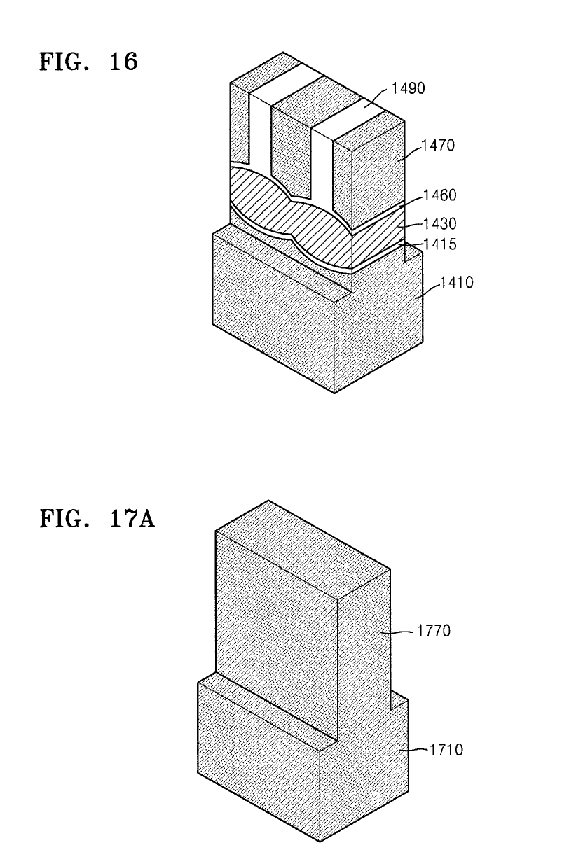

FIG. 16 illustrates the case where the BOX region 1415, the gate pattern 1430, and the gate insulating region 1460 are formed between the substrate region 1410 and the body region 1470 in FIG. 14.

In FIGS. 15 and 16, the body region 1470 is separated from the substrate region 1410. In this case, as the substrate region 1410 and the body region 1470 are formed on the same substrate, the substrate region 1410 and the body region 1470 may include the same material. A process of selectively etching the middle portion of a substrate can be further understood with reference to, for example, Sphere-shaped-Recess-Channel-Array Transistor (S-RCAT) Technology for 70 nm DRAM feature size and beyond, 2005 Symposium on VLSI Technology Digest of Technical Papers, and the disclosure of which is hereby incorporated by reference herein in its entirety.

When the body region 1470 is formed on the substrate region 1410 by epitaxial growing, the materials included in the body region 1470 and the substrate region 1410 should not have the same properties. Rather, the materials should have different properties from one another.

The semiconductor substrate according to the present exemplary embodiment may be formed from a bulk semiconductor substrate. That is, the body region 1470 may be formed from the bulk semiconductor substrate by, for example, selectively etching the middle portion of the bulk semiconductor substrate.

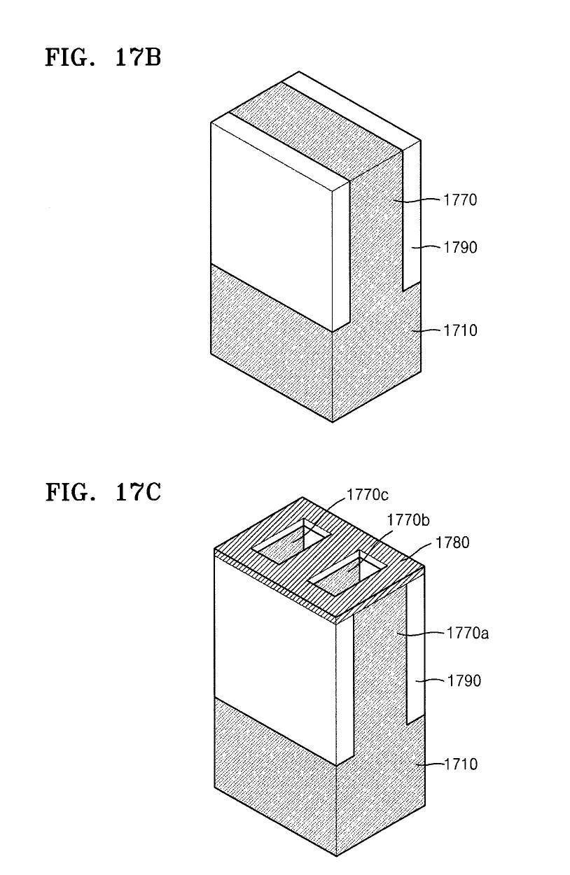

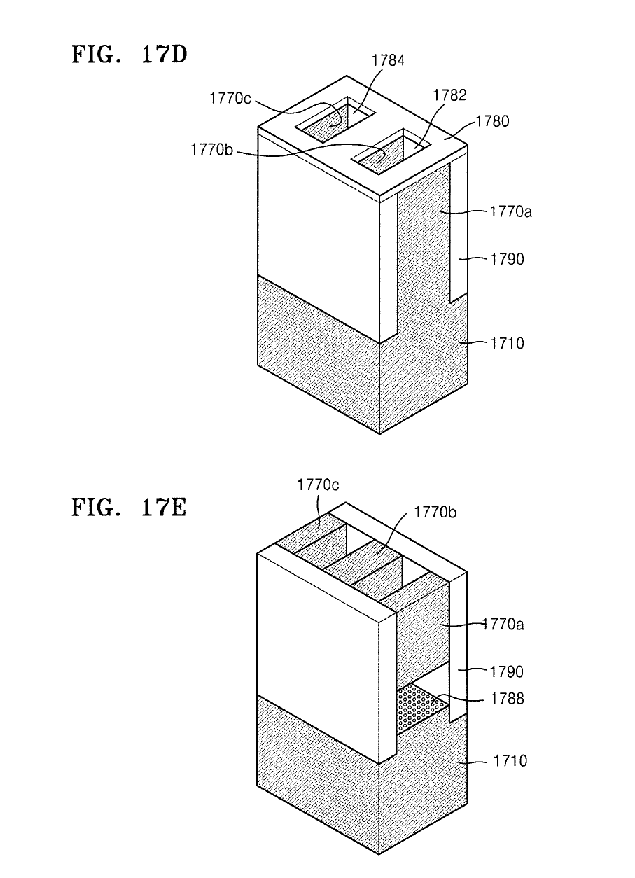

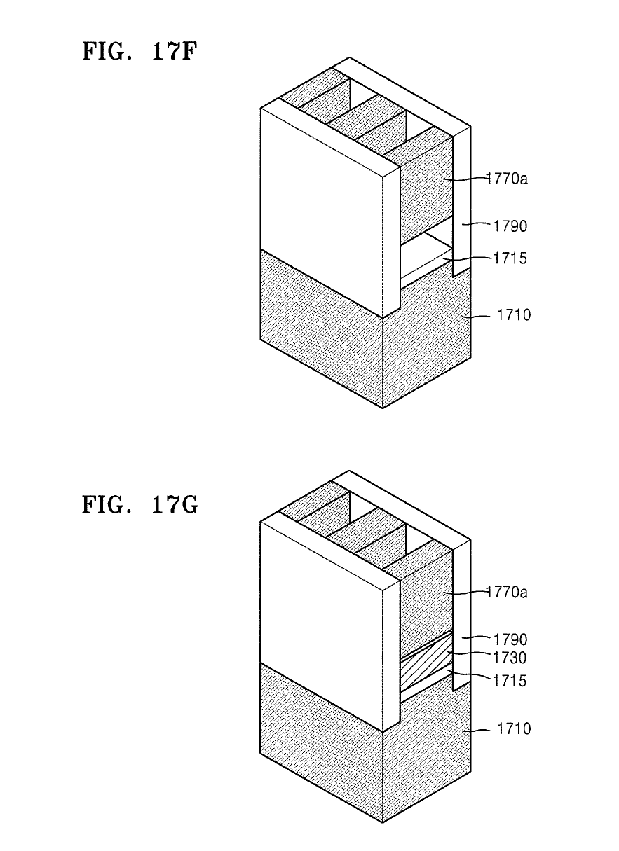

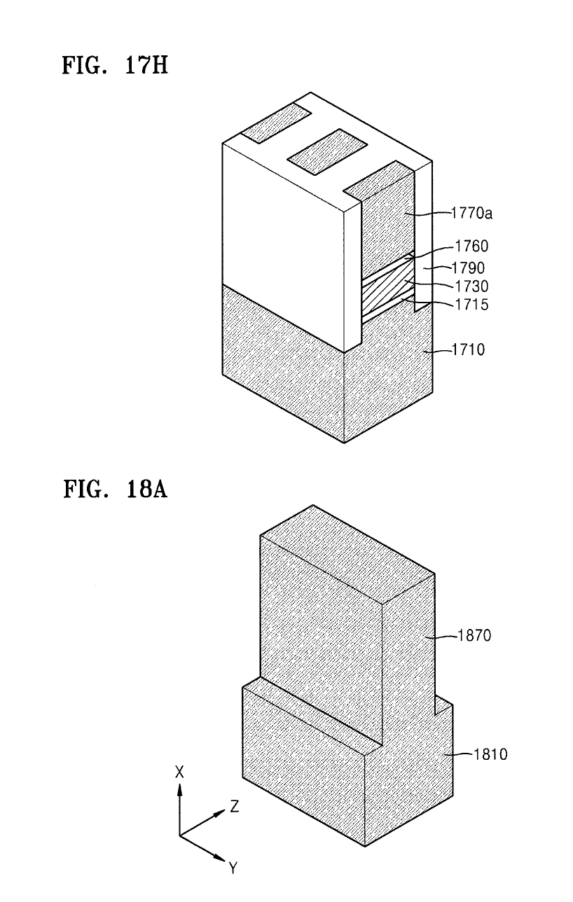

FIGS. 17A through 17H are perspective views of a method of manufacturing a semiconductor device, according to an exemplary embodiment of the present invention.

Referring to FIG. 17A, a body line pattern 1770 extending in a first direction (e.g., a Y direction) is formed by etching a bulk substrate in the first direction (e.g., the Y direction). That is, upper ends of both edges of a semiconductor substrate may each be patterned by a predetermined width and a predetermined length. The semiconductor substrate may be a bulk semiconductor substrate formed from a bulk wafer. As a result of the patterning, the body line pattern 1770 is formed between the patterned portions and a substrate region 1710 is formed below the body line pattern 1770. A part of the body line pattern 1770 is formed as a body region 1770a (see FIG. 17H). According to the width required for the body region 1770a, the width of a portion to be patterned may be varied. According to the thickness required for the body region 1770a, the length of the portion to be patterned may be varied.

Referring to FIG. 17B, an insulating material is filled in both sides of the body line pattern 1770, thereby forming first insulating regions 1790. As a result, the first insulating regions 1790 are disposed on both side surfaces of the first insulating regions 1790. The first insulating regions 1790 may support the body region 1770a when the body line pattern 1770 is separated from the substrate region 1710 to form the body region 1770a by selective etching.

Referring to FIG. 17C, the body line pattern 1770 is patterned in a second direction (e.g., a Z direction). The body line pattern 1770 is etched in the second direction (e.g., the Z direction) perpendicular to the first direction in which the body line pattern 1770 extends, except for the first insulating regions 1790. Thus, body patterns 1770a, 1770b and 1770c extending in the first direction are formed. In FIG. 17C, the first insulating regions 1790 are not patterned. In a patterning operation illustrated in FIG. 17C, the body line pattern 1770 may be patterned to a predetermined length, from an upper end thereof.

Portions of the body line pattern 1770, which are not to be patterned, and the first insulating regions 1790 are covered by a mask 1780, and then the patterning operation may proceed with respect to only a portion that is not covered by the mask 1780.

Referring to FIG. 17D, inner surfaces 1782 and 1784 of the patterned portions and a bottom surface are masked, and then a mask of the bottom surface is removed. Then, lower ends of the body patterns 1770a, 1770b and 1770c are selectively etched through the bottom surface of which the mask has been removed. In FIG. 17E, the lower ends of the body patterns 1770a, 1770b and 1770c are selectively etched, and a bottom surface 1788 of the body patterns 1770a, 1770b and 1770c is exposed. As a result, the body regions 1770a, 1770b and 1770c separated from the substrate region 1710 are formed.

Throughout this specification, prior to separating regions 1770a, 1770b and 1770c from the substrate region 1710, the regions 1770a, 1770b and 1770c are referred to as the body patterns 1770a, 1770b and 1770c. After separating region 1770a, 1770b and 1770c from the substrate region 1710, the regions 1770a, 1770b and 1770c are referred to as the body regions 1770a, 1770b and 1770c.

Referring to FIG. 17F, an insulating material may be deposited on a portion that has been selectively etched, thereby forming a BOX region 1715. Then, a gate pattern 1730 may be formed on the BOX region 1715. Next, referring to FIG. 17H, an insulating material is deposited on the gate pattern 1730, thereby forming the gate insulating region 1760.

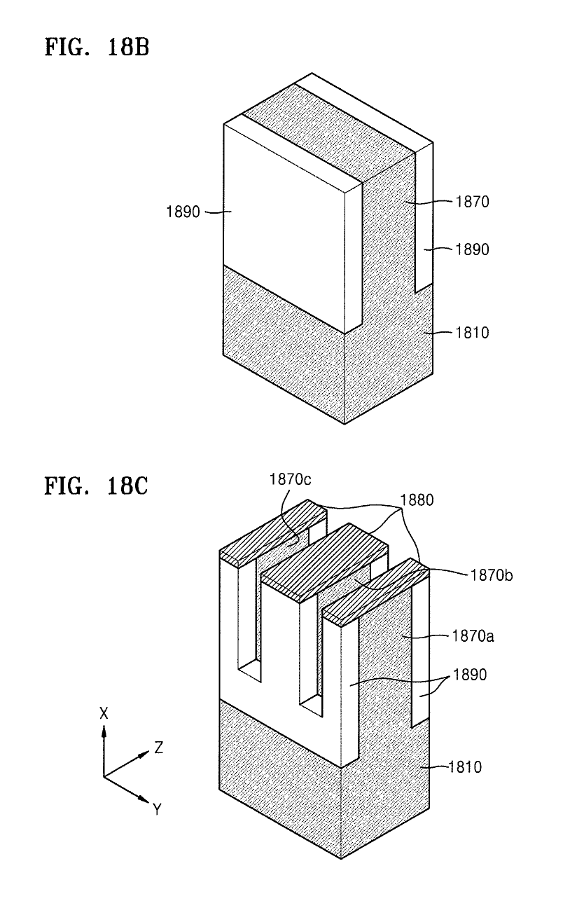

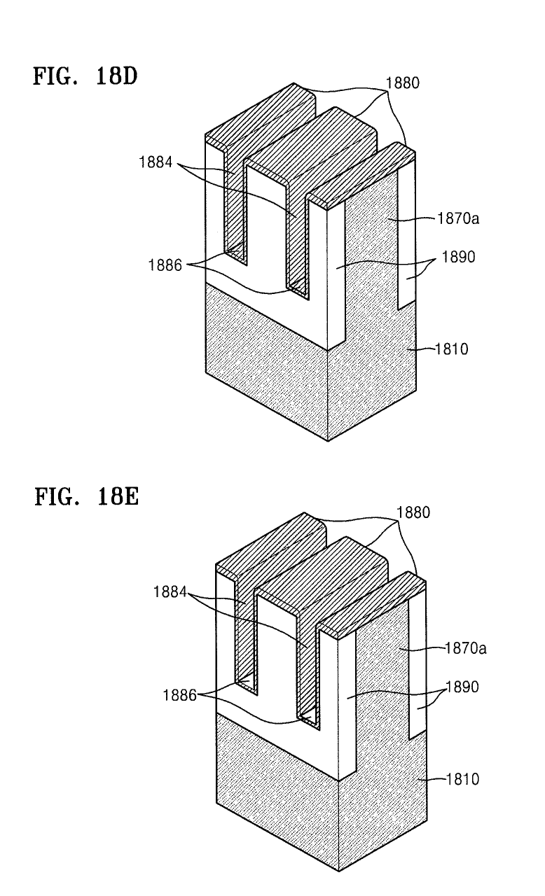

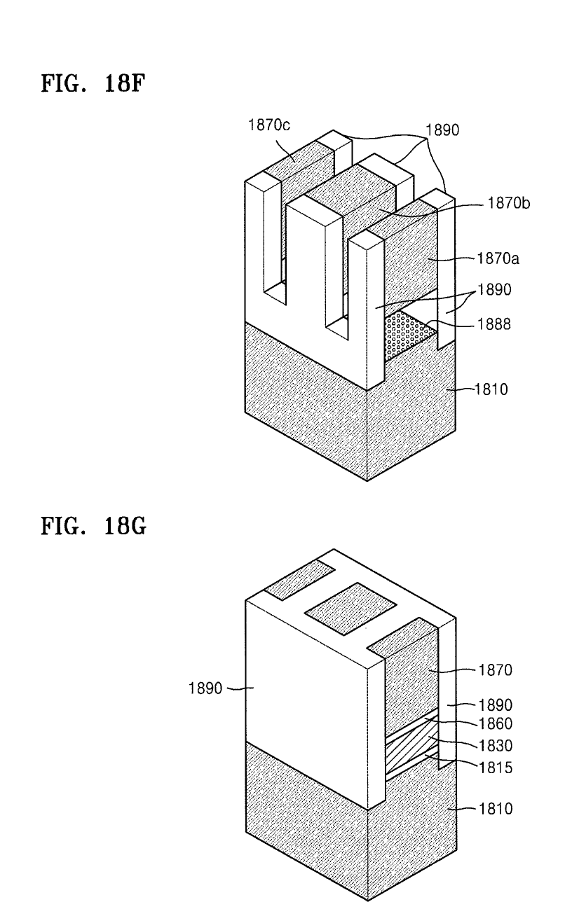

FIGS. 18A through 18G are perspective views of a method of manufacturing a semiconductor device, according to another exemplary embodiment of the present invention.

Referring to FIG. 18A, a body line pattern 1810 extending in a first direction (e.g., a Y direction) that is a major axis direction is formed by etching a bulk substrate in the first direction. Referring to FIG. 18B, an insulating material is filled in both sides of the body line pattern 1810, thereby forming first insulating regions 1890. Operations of FIGS. 18A and 18B are the same operations as FIGS. 17A and 17B, respectively, and thus their descriptions will not be repeated here.

Referring to FIG. 18C, a body line pattern 1870 and the first insulating regions 1890 are patterned in a second direction (e.g., a Z direction). The body line pattern 1870 is etched in the second direction (e.g., the Z direction) perpendicular to the first direction in which the body line pattern 1870 extends. Thus, body patterns 1870a, 1870b and 1870c extending in the second direction are formed. The first insulating regions 1790 are not patterned in FIG. 17C. However, the first insulating regions 1890 are patterned in FIG. 18C. In a patterning operation illustrated in FIG. 18C, the body line pattern 1870 may be patterned to a predetermined length, from an upper end thereof.

Portions of the body line pattern 1870 and portions of the first insulating regions 1890, which are not to be patterned, are covered by a mask 1880, and then the patterning operation may proceed with respect to only a portion that is not covered by the mask 1880.

Referring to FIGS. 18D and 18E, an inner surface 1884 and a bottom surface 1886 are masked, and then a mask of the bottom surface 1886 is removed. Then, lower ends of the body patterns 1870a, 1870b and 1870c are selectively etched through the bottom surface 1886 of which the mask has been removed. In FIG. 18F, the lower ends of the body patterns 1870a, 1870b and 1870c are selectively etched, and a bottom surface 1888 of the body patterns 1870a, 1870b and 1870c are exposed. As a result, the body regions 1870a, 1870b and 1870c separated from the substrate region 1810 are formed.

Referring to FIG. 18G, an insulating material may be deposited on a portion that has been selectively etched, thereby forming a BOX region 1815. A gate pattern 1830 may be formed on the BOX region 1815. Then, an insulating material is deposited on the gate pattern 1830, thereby forming the gate insulating region 1860.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A semiconductor device comprising:
a semiconductor substrate;
a gate pattern disposed on the semiconductor substrate;
a body region disposed on the gate pattern; and
a first impurity doping region and a second impurity doping region, and wherein the gate pattern is disposed below the body region and the first impurity doping region and the second impurity doping region.

2. The semiconductor device of claim 1, wherein the first impurity doping region and the second impurity doping region protrude in an upwards direction from the body region, and are spaced a predetermined interval apart; and
wherein the semiconductor device further comprises a block insulating region disposed between the first impurity doping region and the second impurity doping region.

3. The semiconductor device of claim 1, further comprising a buried oxide (BOX) insulating region disposed between the semiconductor substrate and the gate pattern.

4. The semiconductor device of claim 1, further comprising a gate insulating region disposed between the gate pattern and the body region.

5. The semiconductor device of claim 1, further comprising a first insulating region disposed at both sides of each of the gate pattern and the body region, wherein the first insulating region insulates the gate pattern and the body region from their surroundings.

6. The semiconductor device of claim 1, wherein the first impurity doping region is connected to one of a source line or a bit line; and
wherein the second impurity doping region is connected to one of a bit line or a source line.

7. The semiconductor device of claim 1, wherein the semiconductor device comprises a bipolar junction transistor (BJT);
wherein the gate pattern is coupled to a base region of the BJT; and
wherein the first and second impurity doping regions are an emitter region and a collector region, respectively, or, the first and second impurity doping regions are a collector region and an emitter region, respectively.

8. The semiconductor device of claim 1, wherein the semiconductor device comprises a BJT; and
wherein a base region of the BJT is floating.

9. The semiconductor device of claim 1, wherein the body region is a floating body region separated from the semiconductor substrate; and
wherein the body region and the semiconductor substrate are formed of materials having the same properties.

10. A semiconductor substrate comprising:
a substrate region;
a buried oxide (BOX) insulating region disposed above the substrate region;
a gate pattern separated from the substrate by a first insulating region, and disposed above the BOX insulating region;
a gate insulating region disposed above the gate pattern; and
a floating body region separated from the gate pattern by the gate insulating region, and disposed on the gate insulating region,
wherein the substrate region and the floating body region are formed of materials having the same properties.

11. The semiconductor substrate of claim 10, wherein the substrate region is formed from a bulk semiconductor substrate.

12. The semiconductor substrate of claim 10, wherein the BOX insulating region or the gate insulating region is formed of silicon oxide.

13. The semiconductor substrate of claim 1, wherein a thickness of the floating body region varies.

14. A semiconductor device comprising:
a semiconductor substrate;
at least one gate pattern disposed on the semiconductor substrate;
at least one body region disposed on the at least one gate pattern; and
a first impurity doping region and a second impurity doping region, which are disposed on the at least one body region.

15. The semiconductor device of claim 14, wherein the first impurity doping region and the second impurity doping region protrude in an upwards direction from the at least one body region, and are spaced a predetermined interval apart, and
wherein the semiconductor device further comprises a block insulating region disposed between the first impurity doping region and the second impurity doping region.

16. The semiconductor device of claim 14, further comprising a buried oxide (BOX) insulating region disposed between the semiconductor substrate and the at least one gate pattern.

17. The semiconductor device of claim 14, further comprising a gate insulating region disposed between the at least one gate pattern and the at least one body region.

18. The semiconductor device of claim 14, further comprising a first insulating region disposed at both sides of the at least one gate pattern and the at least one body region disposed on the at least one gate pattern, and wherein the first insulating region insulates the at least one gate pattern and the at least one body region from their surroundings.

19. The semiconductor device of claim 14, wherein the first impurity doping region is connected to one of a source line or a bit line; and
wherein the second impurity doping region is connected to one of a bit line or a source line.

20. A method of manufacturing a semiconductor substrate, the method comprising:
forming at least one floating body pattern by etching a bulk substrate;
dividing the bulk substrate into a substrate region and a floating body region by etching a bulk region below the at least one floating body pattern; and
forming a gate pattern between the floating body region and the substrate region.
